(19) United States
(12) Patent Application Publication
(10) Pub. No.: US 2004/0182432 A1
(43) Pub. Date: Sep. 23, 2004

(54) Photovoltaic module subassembly and photovoltaic module with sealed insulating glass

(75) Inventors: Hiroyuki Yoda, Kitakatsuragi-gun (JP); Kousuke Ueda, Ikoma-gun (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/780,696

(22) Filed: Feb. 19, 2004

(30) Foreign Application Priority Data
Mar. 19, 2003 (JP) 2003-075513(P)

(51) Int. Cl. H01L 31/00

(52) U.S. Cl. 136/244; 136/251

(57) ABSTRACT

A photovoltaic module with sealed insulating glass includes opposite, front and rear plates of glass, a frame forming a space therebetween, and a photovoltaic module subassembly arranged in the space. The subassembly includes a plurality of photovoltaic cells, a first, translucent plate member of resin located adjacent to a light receiving surface of the cell, a second, translucent plate member of resin located adjacent to a non-light receiving surface of the cell, and a translucent filler layer located between the plate members of resin to seal the photovoltaic cells. Thus the photovoltaic module with sealed insulating glass can be reusable and excellent in sound and heat insulation, and also miniaturized and significantly strong and highly antiweatherable.

This nonprovisional application is based on Japanese Patent Application No. 2003-75513 filed with the Japan Patent Office on Mar. 19, 2003, the entire contents of which are hereby incorporated by reference.

### BACKGROUND OF THE INVENTION

1. Field of the Invention

The present invention relates to photovoltaic module subassemblies and photovoltaic modules having the subassembly arranged between sealed insulating glass.

2. Description of the Background Art

In recent years, a photovoltaic system converting solar energy into electrical energy is increasingly used as a power generation means utilizing clean energy. This system employs a photovoltaic module including a photovoltaic module of a type installed for example on a roof of a building as well as a photovoltaic module formed of sealed insulating glass and a photovoltaic panel integrated together, or a photovoltaic module with sealed insulating glass, as known in the field. The photovoltaic module with sealed insulating glass is capable of introducing sunlight through a gap formed between a plurality of photovoltaic cells arranged in an array. Accordingly the module is applied to windows provided in walls of residences, buildings and the like, and skylights provided in ceilings, and is also expected to be applied to sound insulation walls provided along roads, arcades and the like.

This type of photovoltaic module with sealed insulating glass is disclosed for example in Japanese Utility Model Laying-Open No. 61-177464, and Japanese Patent Laying-Open Nos. 10-1334 and 11-31834. These documents disclose photovoltaic modules structured to include opposite two plates of glass either one of which has a surface opposite the other and having a photovoltaic cell stuck thereon.

The photovoltaic modules with sealed insulating glass as disclosed in the above documents, however, have photovoltaic cells attached for example by adhesion to one of two opposite plates of glass. This prevents the photovoltaic cells alone from being exchanged, and it is also difficult to reuse the cells. This problem is significantly remarkable when efflorescence occurs.

Efflorescence is precipitation of sodium hydrogen carbonate on a surface of a plate of glass placed outdoors for a long period of time. When a photovoltaic module with sealed insulating glass suffers efflorescence the module provides a significantly reduced ray transmittance and an accordingly significantly reduced amount of power generated, despite that the photovoltaic cells themselves do not have any failure. If the plates of glass alone can be exchanged, the photovoltaic cells can be reused.

For the photovoltaic module with sealed insulating glass thus structured, however, it is difficult to exchange the plates of glass alone, and it is unavoidable to exchange the entire module. Furthermore, it is also unavoidable that the removed module be discarded although its photovoltaic cells do not have failure.

Another conventional, known photovoltaic module with sealed insulating glass is that with so-called joined glasses, as shown in the FIG. 11 structure. A photovoltaic module with joined glasses 101 includes a photovoltaic cell 121 fragile and significantly susceptible to whether and two plates of glass 111 and 118 significantly strong and highly antiweatherable and sandwiching photovoltaic cell 121. More specifically, a plurality of photovoltaic cells 121 arranged in an array are sealed between opposite, front and internal plates of glass 111 and 118 by a filler layer 125. This structure is generally referred to as a photovoltaic module subassembly 120 with joined glasses.

Furthermore, the intermediate plate of glass 118 has a main surface facing away from photovoltaic cell 121 and having a rear plate of glass 112 attached thereto via a spacer member 113. Spacer member 113 allows an air layer 114 to be formed between the intermediate plate of glass 118 and the rear plate of glass 112. Air layer 114 effectively insulates sound, heat and the like.

Photovoltaic module 101 thus configured has a structure when it is exploded, as shown in FIG. 12, and it is fabricated in a procedure as described hereinafter.

Initially, a plurality of photovoltaic cells 121 arranged in an array and electrically interconnected by a conductive wire 122 are prepared. Then the plurality of photovoltaic cells 121 are sandwiched vertically by thermosetting, adhesive films 125a. These components are then sandwiched vertically by the front plate of glass 111 and the intermediate plate of glass 118. Thus the front plate of glass 111, adhesive film 125a, photovoltaic cells 121, adhesive film 125a and the intermediate plate of glass 118 provide a stack of layers, which is in turn placed in a vacuum and receives a pressure of approximately 1 kg/cm³ and is thus heated for thermal fusion to fabricate photovoltaic module assembly with joined glasses 121. Note that this process is referred to as a lamination process. After this subassembly is cooled, the rear plate of glass 112 is attached to the intermediate plate of glass 118 with spacer member 113 posed therebetween. Photovoltaic module with joined glasses 101 as shown in FIG. 11 is thus fabricated.

The FIG. 11 photovoltaic module with joined glasses requires three plates of glass to effectively insulate sound, heat and the like. This causes a large number of problems including a device disadvantageously increased for example in weight and thickness. Furthermore when between rigid plates of glass a filler in the form of a film, a liquid filler or the like is used in the lamination process to seal photovoltaic cells, stress affects and thus often causes the cells for example to crack or chip, which contributes to reduced yields. If in the lamination process a cell has cracked or chipped the entirety must be discarded as the cells are individually unexchangeable.

Furthermore, for the FIG. 11 module, as well as those disclosed in the aforementioned documents, when the front or intermediate plate of glass suffers efflorescence, the module must entirely be exchanged and the photovoltaic cells cannot be reused.

Conventional battery modules with sealed insulating glass thus have a large number of disadvantages.

### SUMMARY OF THE INVENTION

The present invention contemplates a photovoltaic module superior in handleability and providing increased yields, and also a photovoltaic module with sealed insulating glass that employs this photovoltaic module subassembly to allow the same to be reusable and provide excellent sound and heat insulation and be also miniaturized and enhanced in strength and antiweatherability.

The present invention provides a photovoltaic module subassembly including photovoltaic cells, first and second plate members of resin, and a filler layer. The photovoltaic cells are arranged in an array and electrically interconnected. The first plate member of resin is a translucent member located adjacent to the plurality of photovoltaic cells' light receiving surface. The second plate member of resin is located adjacent to the cells' non-light receiving surface. The filler member is a translucent layer located between the first and second plate members of resin to seal the plurality of photovoltaic cells arranged in the array. As the photovoltaic cells are introduced in a filler layer formed between two plate members of resin, the subassembly can be excellent in handleability as it is lightweight. Furthermore, a lamination process can be performed with the photovoltaic cells receiving a reduced stress to allow fabrication with increased yields.

In the present subassembly for example the first plate member of resin is preferably formed of a film containing flouroresin as a source material. Using flouroresin to form the first plate member of resin can provide appropriate rigidity to the first plate member of resin and also allows the subassembly to be highly antiweatherable as it does not change in color when it is exposed to high temperature and high humidity.

In the present subassembly for example the first plate member of resin is preferably a stack of a film containing fluororesin as a source material and a film containing polyethylene terepthalate as a source material. Thus using fluororesin and polyethylene terephthalate to form the first plate member of resin can provide appropriate rigidity to the first plate member of resin and also allows the subassembly to be highly antiweatherable as it does not change in color when it is exposed to high temperature and high humidity. Note that if the second plate member of resin is translucent, then, similarly as has been described for the first plate member of resin, the second plate member of resin is preferably formed of a film containing fluororesin as a source material or a stack of a film containing fluororesin as a source material and a film containing polyethylene terephthalate resin as a source material.

In the present subassembly for example the second plate member of resin is preferably a translucent member. The second plate member of resin that is translucent allows light to be introduced at a portion other than that having the photovoltaic cells. The subassembly can be contemplated to establish both of power generation and light introduction.

In the present subassembly for example at least one of the first and second plate members of resin is preferably colored and transparent. By the colored and transparent plate member(s) of resin, light that is introduced through a gap between the cells arranged in an array can be controlled in hue, brightness, contrast and the like, as desired, for example to provide a room's interior with a unique, effective presentation.

In the present subassembly for example at least one of the first and second plate members of resin preferably contains an ultraviolet absorber. The UV absorber can prevent the plate member(s) of resin from yellowing and also eliminate ultraviolet rays harmful to the human body from light introduced between the cells arranged in an array.

In the present subassembly for example the filler layer preferably contains as a source material a resin selected from the group consisting of ethylene-vinyl acetate (EVA) resin, polyvinyl butyral (PVB) resin, and silicon resin. The filler layer formed of resin of these materials allows the subassembly to be highly antiweatherable as it does not change in color when it is exposed to high temperature and high humidity.

In the present subassembly for example a pouching lamination apparatus is preferably used to perform a lamination process to seal the photovoltaic cells in the filler layer. As the above described subassembly can be fabricated using a pouching lamination apparatus it can be more readily fabricated than conventional. Furthermore, the plate member of resin is smaller in rigidity than a conventionally used substrate of glass and the lamination process can be performed with the photovoltaic cells receiving a significantly alleviated stress. Significantly increased yields can thus be expected.

In the present subassembly for example the plurality of photovoltaic cells each preferably has a light receiving surface unbonded to the filler layer. An increased amount of light can be transmitted and the photovoltaic cells can thus generate an increased amount of power. Furthermore, the lamination process can be performed with the photovoltaic cells receiving a significantly alleviated stress and increased yields can be expected.

In the present subassembly preferably a conductive wire electrically connecting said plurality of photovoltaic cells and also allowing an external, electrical output is provided in said filler layer and said filler layer has an end provided with an output terminal electrically connected to the conductive wire. This configuration allows an output to be relatively readily extracted from the photovoltaic cells.

The present invention provides a photovoltaic module with sealed insulating glass including first and second plates of glass, a spacer member, and a photovoltaic module subassembly. The spacer member forms a space between the first and second plates of glass. The second plate of glass is arranged opposite the first plate of glass. The subassembly includes a plurality of photovoltaic cells arranged in an array and electrically interconnected, a translucent, first plate member of resin adjacent to a light receiving surface of the plurality of photovoltaic cells, a second plate member of resin adjacent to a non-light receiving surface of the plurality of photovoltaic cells, and a translucent filler layer located between the first and second plate members of resin to seal the plurality of photovoltaic cells. The subassembly is arranged in the space formed by the spacer member. The module can thus be reduced in weight and thickness.

In the present module for example the subassembly is preferably arranged to cooperate with at least one of the first and second plates of glass to sandwich an air layer therebetween. An air layer can thus be relative readily formed and the module can provide excellent sound and heat insulation.

In the present module for example preferably the spacer member has butyl rubber attached thereto and the spacer member with the butyl rubber attached thereto is fitted between the first and second plates of glass at their respective ends to pose the butyl rubber between the spacer member and the first and second plates of glass and silicon resin is applied and allowed to set outer than the spacer member between the first and second plates at their respective ends to allow the space between the first and second plate members to be watertight. A relatively inexpensive member can be used to allow the module to be internally watertight. Furthermore, the silicon resin serving as a sealing member cold-sets. This can reduce a defect attributed to thermal stress and provide increased yields.

In the present module for example the subassembly is preferably detachably attached to a frame formed of the first and second plates of glass and the spacer member. The subassembly alone can be extracted from the frame for reuse.

In the present module for example preferably the spacer member is provided with a guide rail sidably holding the subassembly to detachably attach the subassembly to the frame. As the spacer member is provided with a guide rail allowing the subassembly to sidably move thereon, the subassembly can be relatively readily extracted from the frame and can thus be readily repaired for example.

In the present module for example the first and second plates of glass are preferably of different types or a single type selected from the group consisting of sheet glass, white glass (low-iron glass), figured glass, tempered glass, heat-strengthened glass and wired glass. The first and second plates of glass can be of various types and a plate of glass of an appropriate type accommodating a location at which the module is installed can be selected as desired.

As has been described above, the present invention can provide a photovoltaic module subassembly excellent in handleability and providing high yields, and also used to fabricate a photovoltaic module with sealed insulating glass that is reusable and excellent in sound and heat insulation and also miniaturized and significantly strong and highly antiweatherable.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a schematic plan view of a photovoltaic module with sealed insulating glass in accordance with the present invention in a first embodiment;

FIG. 2 is a schematic cross section taken along the FIG. 1 line II-II;

FIG. 3A is an enlarged cross section of an end of the FIG. 2 module;

FIG. 3B is an enlarged cross section of another exemplary configuration of the end of the module;

FIG. 4 is a schematic cross section taken along the FIG. 1 line IV-IV;

FIG. 5 is a perspective view generally showing a configuration of an output terminal portion provided to the FIG. 1 module;

FIG. 6 shows the present module in the first embodiment disassembled;

FIG. 7 is a perspective view generally showing a method of recovering a photovoltaic module subassembly in accordance with the present invention in the first embodiment;

FIG. 8 is a perspective view generally showing the present module in a second embodiment;

FIG. 9 is a schematic cross section taken along the FIG. 1 line IX-IX;

FIG. 10 is an enlarged cross section of an end for illustrating a watertight structure of the present module in a third embodiment;

FIG. 11 is a cross section of a structure of a photovoltaic module with joined glasses, as conventional; and

FIG. 12 shows the conventional module disassembled.

### DESCRIPTION OF THE PREFERRED EMBODIMENTS

Hereinafter the present invention in embodiments will be described with reference to the drawings.

### First Embodiment

The present embodiment provides a photovoltaic module with sealed insulating glass capable of introducing light, and a photovoltaic module subassembly suitable for application to the module.

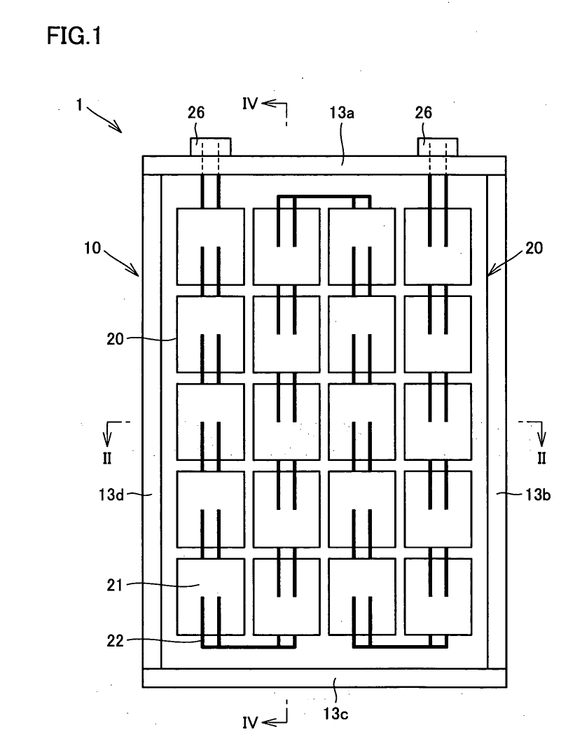

As shown in FIG. 1, the present embodiment provides a photovoltaic module with sealed insulating glass 1 including a frame 10 and a photovoltaic module subassembly 20 incorporated in the frame.

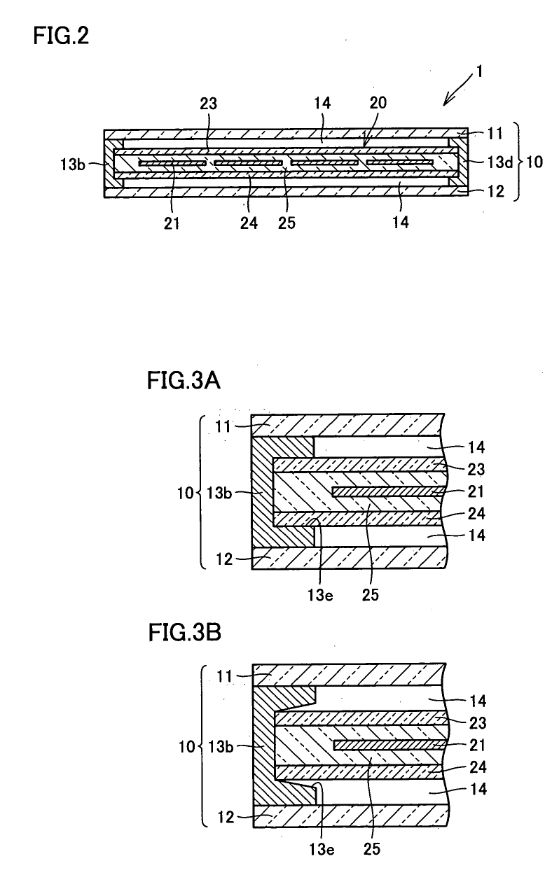

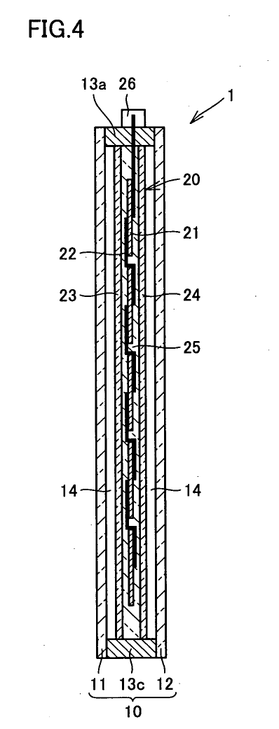

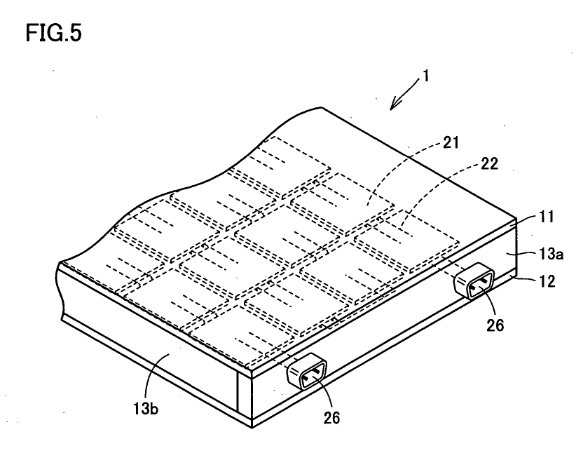

As shown in FIGS. 2 and 4, frame 10 includes a front plate of glass 11 serving as a first plate of glass, a rear plate of glass 12 serving as a second plate of glass and subframes 13a-13d serving as a spacer member.

The front and rear plates of glass 11 and 12 are arranged generally in parallel with their respective main surfaces opposite to each other and uniformly spaced. The front and rear plates of glass 11 and 12 can be formed for example of sheet glass, white glass (low-iron glass), figured glass, tempered glass, heat-strengthened glass or wired glass. Furthermore, the front and rear plates of glass 11 and 12 are not required to be plates of glass identical in type and may be different types of plates of glass. Which type of plate of glass should be used may be determined appropriately by considering for example an environment in which module 1 is installed. For example, if the module is used as a skylight, the plates' strength should be considered and wire glass is accordingly, preferably used.

Between the front and rear plates of glass 11 and 12 subframes 13a-13d are arranged. Subframes 13a-13d are a member of metal or resin arranged as a spacer to allow the front and rear plates of glass 11 and 12 to face each other with a uniform distance posed therebetween. Subframes 13a-13d are arranged on the front side of glass 11 and the rear side of glass 12 along their respective four sides. Thus subframes 13a-13d form a space in frame 10.

Subframes 13a-13c are arranged at opposite ends of module 1 as seen widthwise. Subframes 13b, 13d are arranged at opposite ends of module 1 as seen lengthwise. Subframe 13b, 13d has an end adjacent to the internal space and having a surface recessed to form a guide rail 13e.

As shown in FIG. 1, photovoltaic module subassembly 20 is an assembly including a plurality of photovoltaic cells 21 arranged in an array and electrically interconnected by a conductive wire 22. It is structured, as shown in FIGS. 2 and 4, including first and second plate members of resin 24 and 23, a filler layer 25 posed between members 24 and 23, and the aforementioned, plurality of photovoltaic cells 21 sealed in filler layer 25.

When subassembly 20 completely assembled is considered in handleability, the first plate member of resin 24 is preferably a plate member of resin relatively large, although smaller than a variety of types of plates of glass, in rigidity, and also adequately flexible. When antiweatherability is considered, the first plate member 24 is preferably formed of a material hardly degrading even when it is exposed to high temperature and high humidity for a long period of time. Furthermore, the first plate member 24 is required to be of translucent material to allow solar light incident through the rear plate of glass 12 to illuminate the photovoltaic cells' light receiving surfaces. Accordingly, the first plate member 24 is preferably formed of a film containing fluororesin as a source material, a stack of a film containing fluororesin as a source material and a film containing polyethylene terephtalate (PET) resin, or the like.

When subassembly 20 completely assembled is considered in handleability, the second plate member of resin 23 is preferably a plate relatively large, although smaller than a variety of types of glass, in rigidity, and also adequately flexible. Furthermore, when antiweatherability is considered, the second plate member 23 is preferably formed of a material hardly degrading even when it is exposed to high temperature and high humidity for a long period of time. Furthermore, the second plate member 23 is preferably formed of translucent material so that light incident through the rear plate of glass 12 that is incident past a gap between photovoltaic cells 21 arranged in an array can be introduced for example into a room's interior. Accordingly, the second plate member 23 is preferably formed for example of a film containing fluororesin as a source material, a stack of a film containing fluororesin as a source material and a film containing polyethylene terephtalate (PET) resin as a source material, or the like.

To introduce solar light for example into a room's interior, it is preferable that at least one of the first and second plate members of resin 24 and 23 be a plate member of resin containing an ultraviolet (UV) absorber. The plate member of resin containing the UV absorber is formed by introducing a benzotrizole UV absorber or the like into the plate member of resin being formed. The UV absorber contained in the plate member of resin can reduce yellowing attributed to exposure to ultraviolet rays for a long period of time and thus prevent reduced amounts of power generated. Furthermore, ultraviolet rays are harmful to the human body and cutting ultraviolet rays included in solar light introduced for example into a room's interior is significantly effective.

Furthermore, to introduce solar light for example into a room's interior, it is preferable that at least one of the first and second plate members of resin 24 and 23 be colored and also transparent so that light introduced between photovoltaic cells 21 through a gap into the room's interior can be light with controlled hue, lightness and contrast and other emphasis to allow the interior to effectively have a unique presentation.

Furthermore to introduce solar light for example into a room's interior the first and second plate members of resin 24 and 23 may be identical or different in type. Plate members of resin identical in type allow components to be common. Plate members of resin different in type allow respectively required properties to be assigned.

Filler layer 25 needs to be formed of a filler material hardly damaging photovoltaic cell 21 in the lamination process. Furthermore when antiweatherability is considered the layer is preferably formed of a material hardly degrading when it is exposed to high temperature and high humidity for a long period of time. Furthermore, it must be formed of a translucent filler material to allow solar light incident through the rear plate of glass 12 to illuminate the photovoltaic cell 21 light receiving surface. Accordingly, preferably it is for example a liquid adhesive or an adhesive member in the form of an embossed film and is formed of a filler material formed of resin containing for example ethylene-vinyl acetate copolymer (EVA) resin, polyvinyl butyral (PVB) resin, silicon resin or the like as a source material.

Subassembly 20 as described above is held in the space internal to frame 10 by subframes 13b and 13d. More specifically, as shown in FIG. 3A or 3B, subframe 13b, 13d has an internal side provided with guide rail 13e receiving an end of subassembly 20 to hold the subassembly. Air layer 14 is thus formed between subassembly 20 and the front and rear plates of glass 11 and 12. Air layer 14 is a component essential in exhibiting sound and heat insulation effects, an advantage of sealed insulating glass.

Guide rail 13e provided to the subframe not only lifts and thus holds subassembly 20 in the space internal to frame 10, as described above, but also contributes to improved workability for assembly and reuse. For example, for assembly, subframes 13b, 13d having guide rail 13e are assembled between the front and rear plates of glass 11 and 12 and subassembly 20 is then slid in along guide rail 13e. Furthermore, for reuse, guide rail 13e helps to draw subassembly 20 out of frame 10. This advantage will be described later more specifically.

As shown in FIG. 3A, subframe 13b is in the form of a horseshoe in a cross section as seen in a direction traversing the direction in which it extends. The subframe thus formed is advantageous in that subassembly 20 held hardly flexes. As shown in FIG. 3B, subframe 13b is provided with guide rail 13e having a groove with an inclined sidewall. The subframe thus formed is advantageous in that subassembly 20 can be more smoothly attached to frame 10.

With reference to FIG. 5, the module 1 subframe 13a is provided with an output terminal 26 to externally output electric power generated by the photovoltaic cells.

Conductive wire 22, which is drawn out of photovoltaic cell 21, is buried in filler layer 25 and drawn out to an end of subassembly 20. Conductive wire 22 is connected between subassembly 20 and subframe 13b and conducts to an output terminal provided to subframe 13b. Electric power generated by photovoltaic cell 21 can thus be readily output external to module 1.

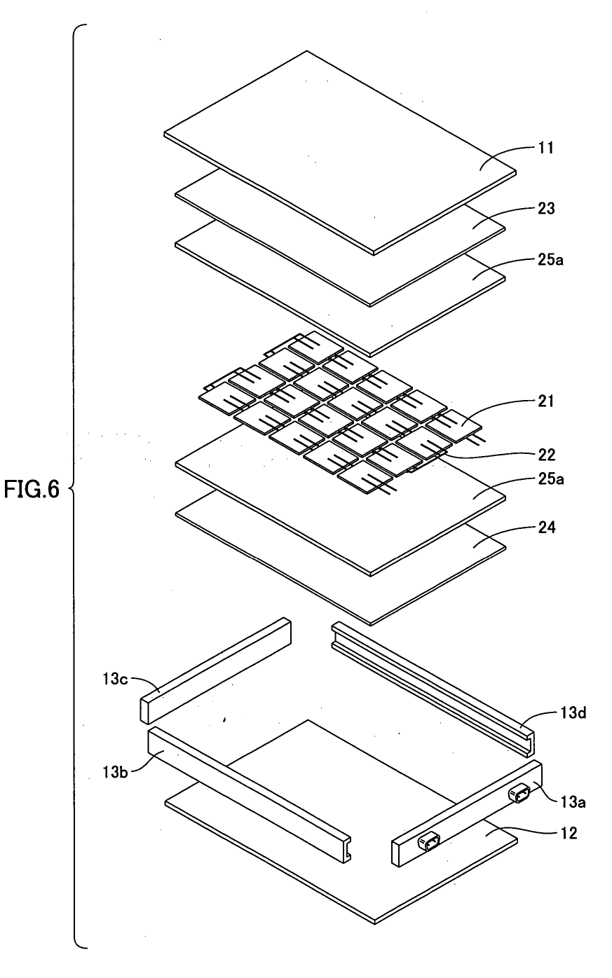

With reference to FIG. 6, the photovoltaic module subassembly and photovoltaic module with sealed insulating glass in the present embodiment are fabricated, as described hereinafter.

Initially, photovoltaic module subassembly 20 is fabricated in a process, as described hereinafter. Photovoltaic cells 21 arranged in an array are previously, electrically connected by conductive wire 22 to configure a power generation circuit. The plurality of photovoltaic cells 21 are then sandwiched by thermosetting, adhesive films 25a vertically. These components are then sandwiched by the first and second plate members of resin 24 and 23 vertically. The first plate member of resin 24, adhesive film 25a, photovoltaic cells 21, adhesive film 25a and the second plate member of resin 23 thus configure a stack of layers, which is then heated with a pressure of approximately 1 kg/cm³ exerted. The stack of layers is thus thermally fused together. More specifically, thermosetting, adhesive film 25a is fused and cooled to form filler layer 25 between the first and second plate members of resin 24 and 23 to seal photovoltaic cells 21. Photovoltaic module subassembly 20 is thus fabricated.

For the lamination process as described above, a so-called pouching lamination apparatus can be used. This apparatus can perform the lamination process with excellent workability as it is a lamination apparatus (a heating and pressurizing apparatus (temperature increase: 150° C., operation time: 30 minutes)) significantly smaller in size and superior in operability than a large-size lamination apparatus (a vacuum heating and pressurizing apparatus (temperature increase: 200° C., operation time: 1 hour)) used to fabricate a conventional, joined glass, photovoltaic module subassembly.

While FIG. 6 shows that adhesive film 25a is not particularly processed such as notched, adhesive film 25a notched at a portion corresponding to a light receiving surface of photovoltaic cell 21 may be used to allow photovoltaic cell 21 having undergone the lamination process to have a light receiving surface unbonded to filler layer 25 to allow photovoltaic cell 21 to generate power more efficiently. It also alleviate a stress exerted during the lamination process on photovoltaic cell 21. Increased yields can be expected.

Photovoltaic module subassembly 20 thus fabricated is used to fabricate photovoltaic module with sealed insulating glass 1 in a process, as will now be described. Initially, the front and rear plates of glass 11 and 12 are prepared. Between the two plates 11 and 12 at their ends subframes 13b-13d are sandwiched and thus mounted. Subframes 13b-13d contact the two plates of glass 11 and 12 at a portion, which is waterproofed. Subassembly 20 then has conductive wire 22 connected to frame 13a at output terminal 26 for example by soldering, as applicable. Then along the subframe 13b, 13d guide rail 13e subassembly 20 is inserted into frame 10. Subframe 13a is attached to subassembly 20. Subframe 13a contacts frame 10 at a portion, which is waterproofed. Photovoltaic module with sealed insulating glass 1 is thus fabricated.

A photovoltaic module subassembly as described above in the present embodiment can be lightweight and significantly superior in handleability. A conventional, joined glass, photovoltaic module subassembly includes a filler layer formed between two plates of glass and receiving photovoltaic cells therein. As such, its overall weight is increased and the plates of glass readily crack or chip and is thus damaged during the assembly process. Using two plate members of resin as employed in the present structure can provide a photovoltaic module subassembly lightweight and hardly damaged. Significantly enhanced handleability can thus be obtained. Furthermore, the lamination process can be simplified and increased yields can also be expected. As such, the photovoltaic module subassembly can be suitable for incorporating into a photovoltaic module with sealed insulating glass.

Furthermore, the photovoltaic module with sealed insulating glass fabricated as described above can be lightweight and reduced in thickness. As has been described above, an air layer can simply and conveniently be introduced between a plurality of layers of glass, and a significantly strong and highly antiweatherable photovoltaic module with sealed insulating glass excellent in sound and heat insulation can be provided.

Furthermore in the present embodiment when the photovoltaic module with sealed insulating glass has its plate(s) of glass damaged or suffering so-called efflorescence the frame alone that includes the plates of glass can be exchanged. As such, the module's photovoltaic module subassembly can effectively be reused. Hereinafter will be described in detail how the subassembly is recovered for reuse.

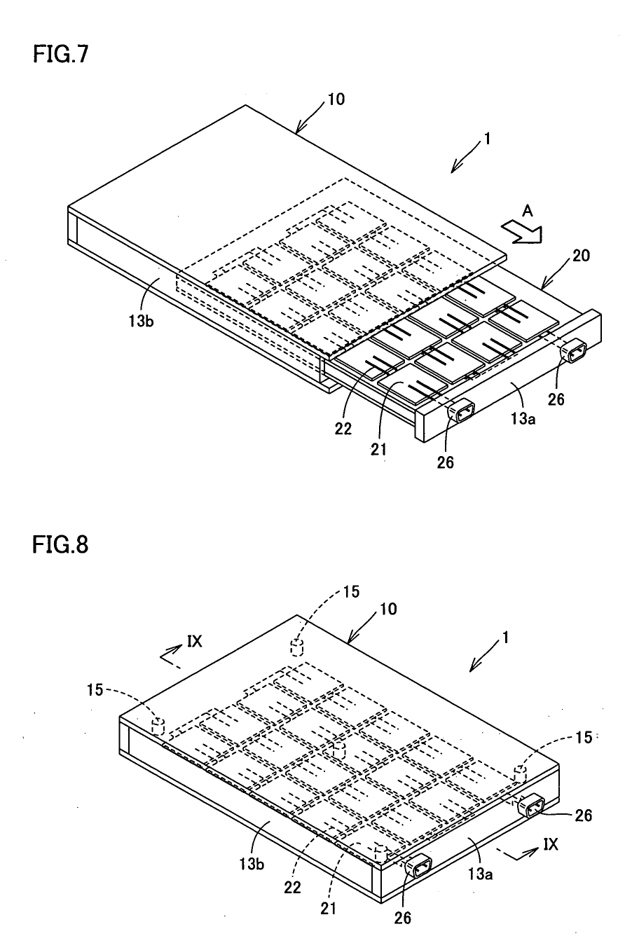

With reference to FIG. 7, subassembly 20 is recovered by removing subframe 13a from frame 10 and extracting it in a direction A. In module 1 of the present embodiment subframes 13b and 13d are provided with guide rail 13e, which allows subassembly 20 to be smoothly extracted. If it is difficult to remove waterproofed subframe 13a from frame 10, subframe 13a may be cut off and subassembly 20 alone may be recovered.

### Second Embodiment

The present embodiment provides a photovoltaic module that is, similarly as has been described in the first embodiment, a photovoltaic module with sealed insulating glass capable of introducing light. Note that components shown in the figures that are similar to those of the first embodiment are identically labeled and will not be described.

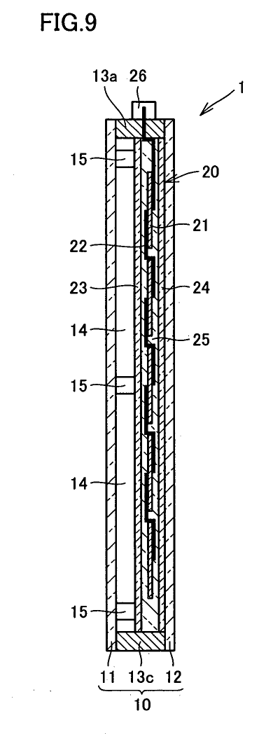

As shown in FIGS. 8 and 9, the present embodiment provides the photovoltaic module with sealed insulating glass 1 structured such that photovoltaic module subassembly 20 arranged in a space internal to frame 10 contacts the rear plate of glass 12. More specifically, it is different from the module described in the first embodiment in that subframes 13a-13d are not provided with a guide rail and an insulative microbead 15 is instead used as a spacer member securing subassembly 20 to frame 10. More specifically, a plurality of columner or spherical microbeads adjusted to have a prescribed height are sandwiched between subassembly 20 and the front plate of glass 11.

This configuration can help to introduce an air layer between the subassembly and the front plate of glass. Furthermore it can help to recover the module for reuse. As such, a photovoltaic module with sealed insulating glass can be provided at a cost lower than in the first embodiment.

Furthermore, while in the present embodiment the subassembly contacts the rear plate of glass by way of example, the subassembly may contact the front plate of glass or the subassembly may have opposite sides facing the front and rear plates of glass, respectively, and having microbeads arranged thereon to form two air layers.

### Third Embodiment

The present embodiment provides a photovoltaic module with sealed insulating glass capable of introducing light, similarly as has been described in the first and second embodiments. While in the first and second embodiments the waterproofed structure has not been described, in the present embodiment the structure will be described in detail.

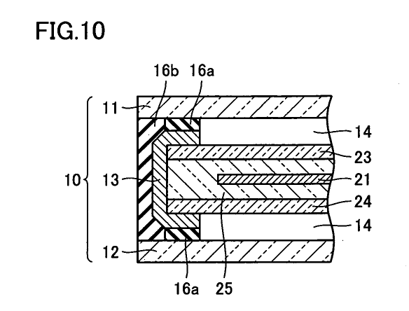

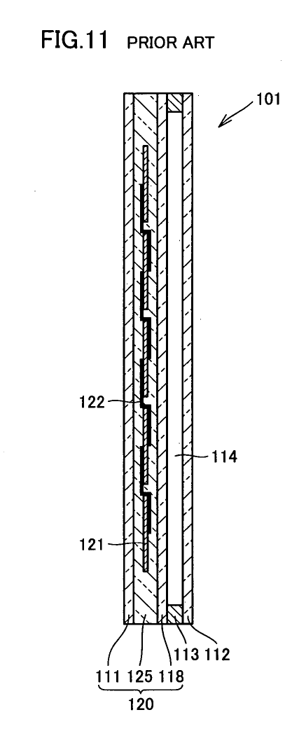

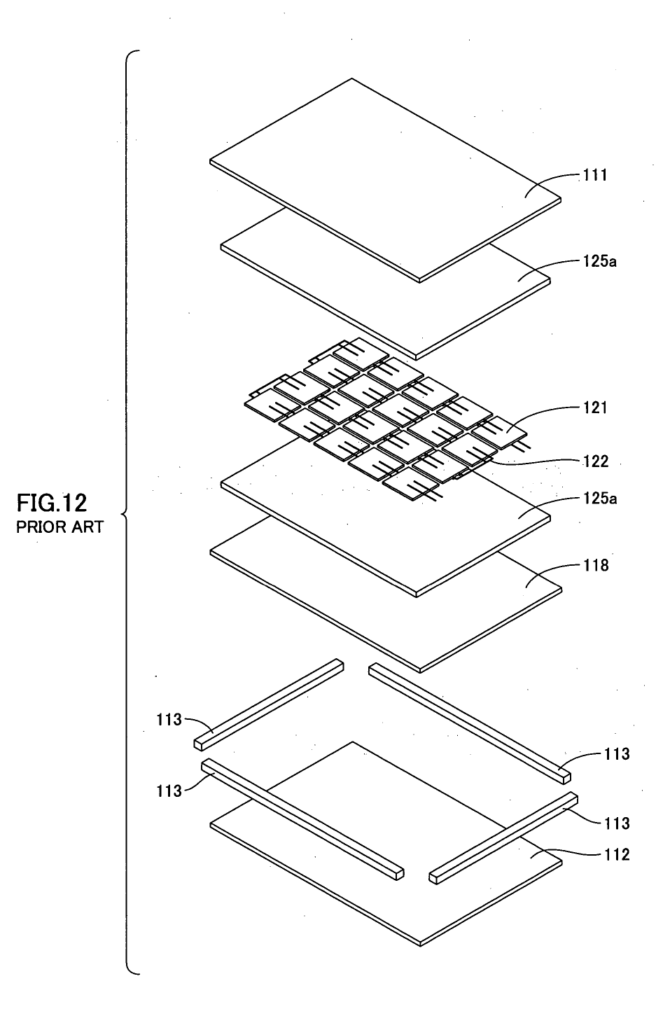

In the present embodiment, as shown in FIG. 10, the photovoltaic module with sealed insulating glass 1 includes frame 10 having an end sealed by butyl rubber 16a and silicon resin 16b. More specifically, subframe 13 with butyl rubber 16a attached thereto is fitted between the opposite, front and rear plates of glass 11 and 12 at their respective ends so that butyl rubber 13a is posed between subframe 13 and the front and rear plates of glass 11 and 12. Cold setting silicon resin 16b is then applied and allowed to set outer than subframe 13 between the front and rear plates of glass 11 and 12 at their respective ends to allow the frame 10 internal space to be watertight.

Such a watertight structure can implement a watertight structure having reliability maintained by a relatively inexpensive member over a long period of time. Conventionally, for reliability, silicon resin has not been used and expensive polysulfide resin has instead been used. Polysulfide resin, however, is thermosetting resin and thus requires a heat treatment after it is applied. In this heat treatment, however, the plates of glass experience thermal stress and an incomplete watertight structure can thus result. The watertight structure as described in the present embodiment can eliminate the necessity of performing the heat treatment to allow resin to set. Thus a watertight structure can be implemented without exerting a large stress on the plates of glass. As a result, significantly increased yields can be achieved.

Variation

While in the first embodiment the module's opposite, longitudinal sides have subframes provided with a guide rail by way of example, the present invention is not particularly limited thereto. For example, it may have four sides all provided with a guide rail or three sides alone provided with a guide rail. Furthermore, as the module may be installed generally horizontally or generally vertically, and a manner other than the guide rail can alternatively be employed to secure the subassembly. In that case if the subassembly is secured at at least one side it will not be positionally displaced inside the frame.

While in the first embodiment not only the first plate member of resin but also the second plate member of resin is translucent by way of example, the second plate member of resin may be a lightproofed member of resin, although in that case light cannot be introduced and as window glass an insufficient function is provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A photovoltaic module subassembly comprising:
a plurality of photovoltaic cells arranged in an array and electrically interconnected;
a translucent, first plate member of resin adjacent to a light receiving surface of said plurality of photovoltaic cells;
a second plate member of resin adjacent to a non-light receiving surface of said plurality of photovoltaic cells; and
a translucent filler layer located between said first and second plate members of resin to seal said plurality of photovoltaic cells.

2. The subassembly of claim 1, wherein said first plate member of resin is a film containing flouroresin as a source material.

3. The subassembly of claim 1, wherein said first plate member of resin is a stack of a film containing fluororesin as a source material and a film containing polyethylene terepthalate as a source material.

4. The subassembly of claim 1, wherein said second plate member of resin is translucent.

5. The subassembly of claim 4, wherein at least one of said first and second plate members of resin is colored and transparent.

6. The subassembly of claim 4, wherein at least one of said first and second plate members of resin contains an ultraviolet absorber.

7. The subassembly of claim 1, wherein said filler layer contains as a source material a resin selected from the group consisting of ethylene-vinyl acetate (EVA) resin, polyvinyl butyral (PVB) resin, and silicon resin.

8. The subassembly of claim 1, wherein said plurality of photovoltaic cells is sealed in said filler layer as said cells undergo a lamination process employing a pouching lamination apparatus.

9. The subassembly of claim 1, wherein said plurality of photovoltaic cells each have a light receiving surface unbonded to said filler layer.

10. The subassembly of claim 1, wherein a conductive wire electrically connecting said plurality of photovoltaic cells and also allowing an external, electrical output is provided in said filler layer and said filler layer has an end provided with an output terminal electrically connected to said conductive wire.

11. A photovoltaic module with sealed insulating glass comprising:
a first plate of glass;
a second plate of glass arranged opposite said first plate of glass;
a spacer member forming a space between said first and second plates of glass; and
a photovoltaic module subassembly arranged in the space formed by said spacer member, said subassembly including
a plurality of photovoltaic cells arranged in an array and electrically interconnected,
a translucent, first plate member of resin adjacent to a light receiving surface of said plurality of photovoltaic cells,
a second plate member of resin adjacent to a non-light receiving surface of said plurality of photovoltaic cells, and
a translucent filler layer located between said first and second plate members of resin to seal said plurality of photovoltaic cells.

12. The module of claim 11, wherein said subassembly is arranged to cooperate with at least one of said first and second plates of glass to form an air layer between said subassembly and said at least one of said first and second plates of glass.

13. The module of claim 11, wherein said spacer member has butyl rubber attached thereto and said spacer member is fitted between said first and second plates of glass at their respective ends to pose said butyl rubber between said spacer member and said first and second plates of glass and silicon resin is applied and allowed to set outer than said spacer member between said first and second plates' respective ends to allow said space to be watertight.

14. The module of claim 11, wherein said subassembly is detachably attached to a frame formed of said first and second plates of glass and said spacer member.

15. The module of claim 14, wherein said spacer member is provided with a guide rail slidably holding said subassembly to detachably attach said subassembly to said frame.

16. The module of claim 11, wherein said first and second plates of glass are of different types or a single type selected from the group consisting of sheet glass, white glass (low-iron glass), figured glass, tempered glass, heat-strengthened glass and wired glass.
